(19) United States
(12) Patent Application Publication
(10) Pub. No.: US 2023/0413605 A1
(43) Pub. Date: Dec. 21, 2023

(54) DISPLAY PANEL AND DISPLAY APPARATUS

(71) Applicant: KunShan Go-Visionox Opto-Electronics Co., Ltd, Kunshan (CN)

(72) Inventors: Junhui LOU, Kunshan (CN); Chao Chi PENG, Kunshan (CN)

(73) Assignee: KunShan Go-Visionox Opto-Electronics Co., Ltd, Kunshan (CN)

(21) Appl. No.: 18/458,592

(22) Filed: Aug. 30, 2023

Related U.S. Application Data
(63) Continuation of application No. PCT/CN2022/108298, filed on Jul. 27, 2022.

(30) Foreign Application Priority Data
Dec. 13, 2021 (CN) 202111517579.5

(51) Int. Cl. H10K 59/121; H10K 59/35; H10K 59/128

(52) U.S. Cl. CPC H10K 59/121; H10K 59/351; H10K 59/65; H10K 59/128; H10K 59/353

(57) ABSTRACT

A display panel and a display apparatus. The display panel includes: sub-pixels including first sub-pixels located in the first display area and second sub-pixels located in the second display area; and pixel driving circuits located in the second display area and including first driving units and second driving units. Each of the first driving units includes one or more first pixel driving circuits for driving the first sub-pixels and N second pixel driving circuits for driving the second sub-pixels, each of the second driving units includes one or more virtual areas and N second pixel driving circuits for driving the second sub-pixels, and an arrangement of the N second pixel driving circuits in the first driving unit is the same as an arrangement of the N second pixel driving circuits in the second driving unit.

### CROSS REFERENCE TO RELATED APPLICATION

This application is a continuation of International Application No. PCT/CN2022/108298 filed on Jul. 27, 2022, which claims priority to Chinese Patent Application No. 202111517579.5 filed on Dec. 13, 2021, both of which are incorporated herein by reference in their entireties.

### TECHNICAL FIELD

The present application relates to the field of display, and particularly to a display panel and a display apparatus.

### BACKGROUND

With the rapid development of electronic devices, demands of users for the screen-to-body ratio are higher and higher, resulting in that the full-screen display of electronic devices attracts more and more attention in the industry.

Electronic devices such as a cell phone and a tablet computer need to integrate a front camera, a telephone receiver, an infrared sensing component and the like. In the prior art, a notch or a hole can be formed in the display screen so that external light can enter the photosensitive component under the screen through the notch or the hole. Nonetheless, these electronic devices do not achieve a real full-screen display, and cannot display an image in all areas of the entire screen. For example, the area corresponding to the front camera of these electronic devices cannot display the image.

### SUMMARY

Embodiments of the present application provide a display panel and a display apparatus, at least part of the display panel can be light-transmitting and can be used for display, which is beneficial for the under-screen integration of the photosensitive components.

Embodiments of a first aspect of the present application provides a display panel including a first display area and a second display area, a light transmittance of the first display area being greater than a light transmittance of the second display area, the display panel including: sub-pixels including first sub-pixels located in the first display area and second sub-pixels located in the second display area; pixel driving circuits located in the second display area and including first driving units and second driving units, each of the first driving units including one or more first pixel driving circuits configured to drive the first sub-pixels and N second pixel driving circuits configured to drive the second sub-pixels, each of the second driving units including one or more virtual areas and N second pixel driving circuits configured to drive the second sub-pixels, an arrangement of the N second pixel driving circuits in the first driving unit being the same as an arrangement of the N second pixel driving circuits in the second driving unit, and N being a positive integer greater than or equal to 2.

Embodiments of a second aspect of the present application provide a display apparatus including the display panel according to the embodiments of the first aspect.

In the display panel according to the embodiments of the first aspect of the present application, the light transmittance of the first display area is greater than the light transmittance of the second display area, so that the photosensitive components can be integrated at the back of the first display area of the display panel to realize under-screen integration for the photosensitive components such as cameras, while the first display area can display images, the display area of the display panel is increased, and a full-screen design is achieved for the display apparatus.

In the display panel according to the embodiments of the first aspect of the present application, the display panel includes the first pixel driving circuits, the second pixel driving circuits and the virtual areas located in the second display area. The first pixel driving circuits are configured to drive the first sub-pixels located in the first display area, and thus the pixel driving circuits for driving the sub-pixels in the first display area are located in the second display area, the light transmittance of the first display area can be further increased. In addition, the virtual areas are arranged in the second display area, so that the arrangement of the N second pixel driving circuits in the first driving unit is the same as the arrangement of the N second pixel driving circuits in the second driving unit, the display consistency of the second display area can be guaranteed, and the display effect of the display panel can be improved.

### BRIEF DESCRIPTION OF THE DRAWINGS

Other features, objects and advantages of the present application will become more apparent from reading the following detailed description of the non-limiting embodiments with reference to the accompanying drawings, in which the same or similar reference numerals represent the same or similar features, and the accompanying drawings are not drawn to actual scale.

FIG. 1 shows a schematic structural diagram of a display panel according to the embodiments of the first aspect of the present application;

FIG. 2 shows a partial enlarged view of an example of area Q in FIG. 1;

FIG. 3 shows a partial enlarged view of another example of area Q in FIG. 1;

FIG. 4 shows a partial enlarged view of yet another example of area Q in FIG. 1;

FIG. 5 shows a partial enlarged view of yet another example of area Q in FIG. 1;

FIG. 6 shows a cross-sectional view at B-B in FIG. 2;

FIG. 7 shows a schematic structural diagram of a display apparatus according to the embodiments of the second aspect of the present application;

FIG. 8 shows a cross-sectional view at D-D in FIG. 7.

### DETAILED DESCRIPTION

Features and exemplary embodiments of various aspects of the present application will be described in detail below. In order to make the objects, technical solutions and advantages of the present application clearer, the present application is further described in detail below with reference to the accompanying drawings and specific embodiments. It should be understood that the specific embodiments described herein are only used to explain the present application, but not to limit the present application. For those skilled in the art, the present application can be implemented without some of these specific details. The following description of the embodiments is only to provide a better understanding of the present application by illustrating examples of the present application.

In an electronic device such as a mobile phone and a tablet computer, photosensitive components such as a front camera, an infrared light sensor, and a proximity light sensor need to be integrated at a side of a the display panel. In some embodiments, a light-transmitting display area may be arranged on the electronic device and the photosensitive components may be arranged at the back of the light-transmitting display area, so that a full-screen display can be achieved for the electronic device while ensuring that the photosensitive components operate normally.

In order to increase the light transmittance of the light-transmitting display area, the driving circuits for the light-transmitting area are often arranged in a non-light-transmitting area, which causes nonuniform display of the non-light-transmitting area of the display panel.

In order to solve the problems described above, the embodiments of the present application provide a display panel and a display apparatus, which will be described below with reference to the accompanying drawings.

The embodiments of the present application provide a display panel, which may be an organic light emitting diode (OLED) display panel.

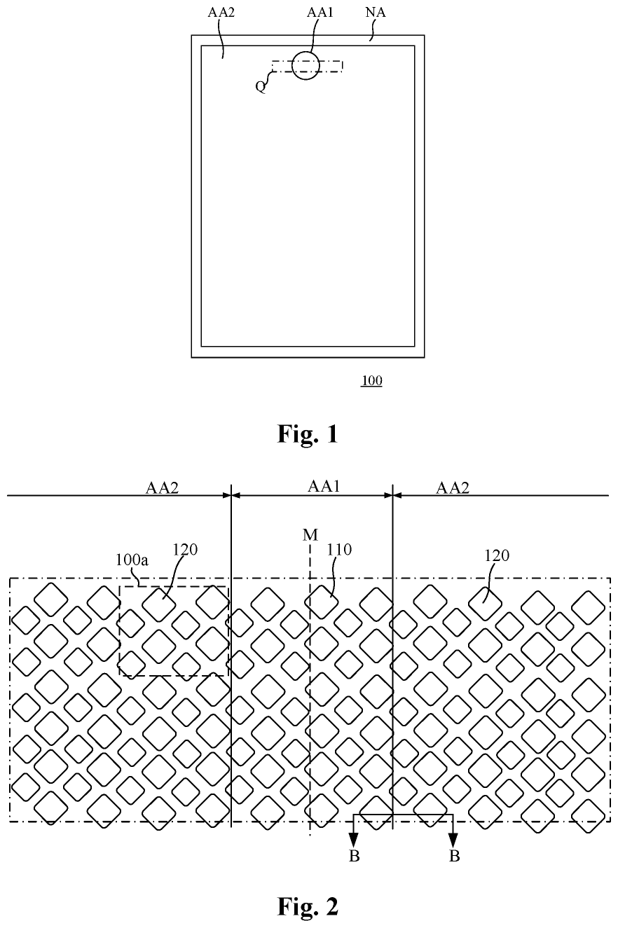

FIG. 1 shows a schematic structural diagram of a display panel according to the embodiments of the first aspect of the present application.

As shown in FIG. 1, the display panel 100 includes a first display area AA1, a second display area AA2, and a non-display area NA surrounding the first display area AA1 and the second display area AA2, and a light transmittance of the first display area AA1 is greater than a light transmittance of the second display area AA2.

Exemplarily, the light transmittance of the first display area AA1 is greater than or equal to 15%. In order to ensure that the light transmittance of the first display area AA1 is greater than 15%, or greater than 40%, or even a higher light transmittance, the light transmittances of various functional film layers of the display panel 100 in the embodiment are all greater than 80%, or even the light transmittances of at least part of the functional film layers are greater than 90%.

In the display panel 100 according to the embodiments of the present application, the light transmittance of the first display area AA1 is greater than the light transmittance of the second display area AA2, so that the photosensitive components can be integrated at the back of the first display area AA1 of the display panel 100 to realize under-screen integration for the photosensitive components such as cameras, while the first display area AA1 can display images, the display area of the display panel 100 is increased, and a full-screen design is achieved for the display apparatus.

The number of the first display area AA1 and the number of the second display area AA2 may be set in a variety of ways, for example, the number of the first display area AA1 is one and the number of the second display area AA2 is one, so as to achieve the under-screen integration for the photosensitive components or fingerprint recognition. Alternatively, in some other embodiments, the number of the first display areas AA1 is two, in which one of the first display areas AA1 is used for the under-screen integration of the photosensitive components and the other one of the first display areas AA1 is used for the fingerprint recognition.

In some embodiments, in order to increase the light transmittance of the first display area AA1, the driving circuits for driving the first display area AA1 will be placed in the second display area AA2. The inventors have found that if the driving circuits for driving the first display area AA1 are placed in the second display area AA2, the driving circuits originally for driving the sub-pixels in the second display area AA2 will be arranged nonuniformly, which in turn affects the display uniformity of the second display area AA2.

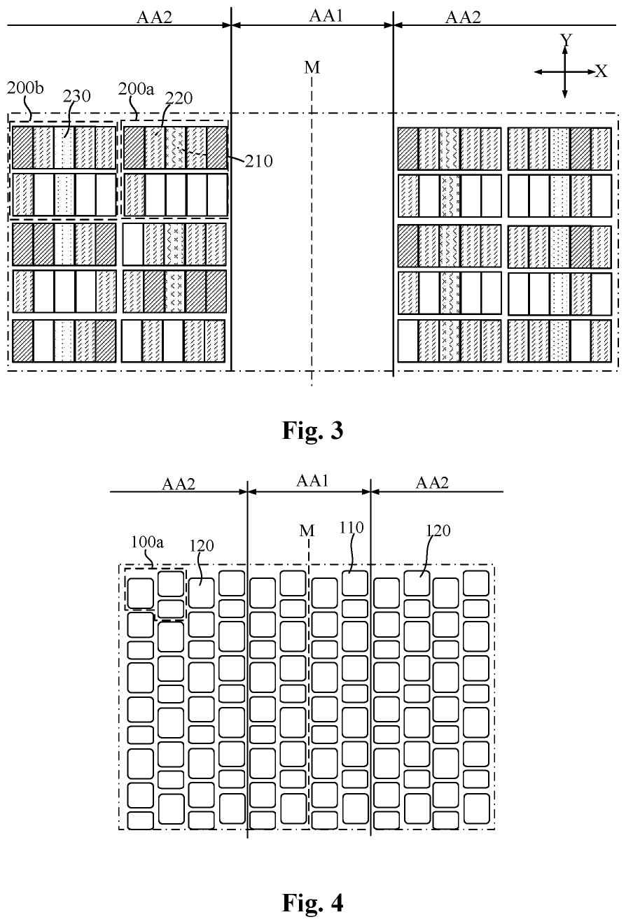

Referring to FIG. 2 and FIG. 3, FIG. 2 shows a partial enlarged schematic structural diagram of area Q in FIG. 1, and FIG. 3 shows a partial enlarged schematic structural diagram of area Q in FIG. 1 in another embodiment. FIG. 2 and FIG. 3 show different layer structures.

As shown in FIG. 2 and FIG. 3, the display panel 100 according to the embodiments of the present application includes sub-pixels and pixel driving circuits. The sub-pixels include first sub-pixels 110 located in the first display area AA1 and second sub-pixels 120 located in the second display area AA2. The pixel driving circuits are located in the second display area AA2 and include first driving units 200a and second driving units 200b, each of the first driving units 200a includes one or more first pixel driving circuits 210 for driving the first sub-pixels 110 and N second pixel driving circuits 220 for driving the second sub-pixel 120, each of the second driving units 200b includes one or more virtual areas 230 and N second pixel driving circuits 220 for driving the second sub-pixels 120, an arrangement of the N second pixel driving circuits 220 in the first driving unit 200a is the same as an arrangement of the N second pixel driving circuits 220 in the second driving unit 200b, and N is a positive integer greater than or equal to 2. The arrangement of the pixel driving circuits is shown in FIG. 3.

In the display panel 100 according to the embodiments of the first aspect of the present application, the display panel 100 includes the first pixel driving circuits 210, the second pixel driving circuits 220 and the virtual areas 230 located in the second display area AA2. The first pixel driving circuits 210 are configured to drive the first sub-pixels 110 located in the first display area AA1, and thus the pixel driving circuits for driving the sub-pixels in the first display area AA1 are located in the second display area AA2, the light transmittance of the first display area AA1 can be further increased. Furthermore, the virtual areas 230 are further arranged in the second display area AA2, so that the arrangement of the N second pixel driving circuits 220 in the first driving unit 200a is the same as the arrangement of the N second pixel driving circuits 220 in the second driving unit 200b, the second pixel driving circuits 220 can be distributed more uniformly in the second display area AA2, the display consistency of the second display area AA2 is guaranteed, and the display effect of the display panel 100 can be improved.

The arrangement of the N second pixel driving circuits 220 in the first driving unit 200a is the same as the arrangement of the N second pixel driving circuits 220 in the second driving unit 200b may mean that the relative positional relationship of the N second pixel driving circuits 220 in the first driving unit 200a is the same as the relative positional relationship of the N second pixel driving circuits 220 in the second driving unit 200b. For example, if the N second pixel driving circuits 220 in the first driving unit 200a are arranged sequentially along the first direction X, the N second pixel driving circuits 220 in the second driving unit 200b are arranged sequentially along the first direction X.

As shown in FIG. 3, if the N second pixel driving circuits 220 in the first driving unit 200a are arranged in two rows and four columns along the first direction X and the second direction Y, and four second pixel driving circuits 220 are arranged in one row, the N second pixel driving circuits 220 in the second driving unit 200b are arranged in two rows and four columns along the first direction X and the second direction Y, and four second pixel driving circuits 220 are arranged in one row.

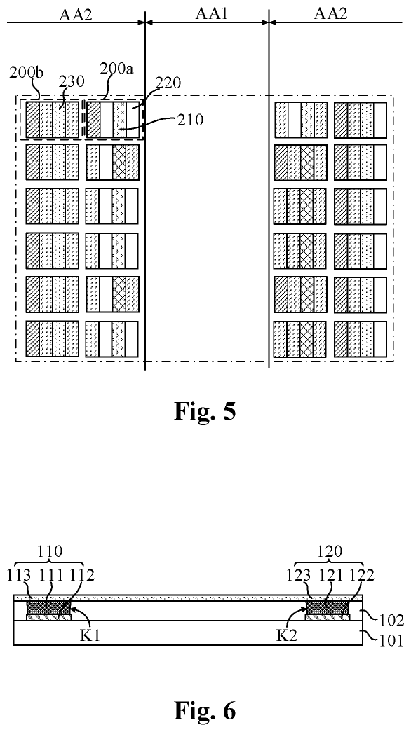

Referring to FIG. 4 and FIG. 5, in some other embodiments, if the N second pixel driving circuits 220 in the first driving unit 200a are arranged in one row and three columns along the first direction X and the second direction Y, and three second pixel driving circuits 220 are arranged in one row, the N second pixel driving circuits 220 in the second driving unit 200b are arranged in one row and three columns along the first direction X and the second direction Y, and three second pixel driving circuits 220 are arranged in one row.

The sub-pixels may be arranged in a variety of ways, and in some embodiments, the first sub-pixels 110 include red sub-pixels, green sub-pixels and blue sub-pixels to achieve the colorized display of the first display area AA1. Exemplarily, the second sub-pixels 120 include red sub-pixels, green sub-pixels and blue sub-pixels to achieve the colorized display of the second display area AA2.

Exemplarily, the second pixel driving circuits 220 include second red driving circuits for driving red sub-pixels to display, second green driving circuits for driving green sub-pixels to display, and second blue driving circuits for driving blue sub-pixels to display. The N second pixel driving circuits 220 in the first driving unit 200a include the second red driving circuits, the second green driving circuits and the second blue driving circuits, the N second pixel driving circuits 220 in the second driving unit 200b include the second red driving circuits, the second green driving circuits and the second blue driving circuits, and the arrangement of the second red driving circuits, the second green driving circuits and the second blue driving circuits in the first driving unit 200a is the same as the arrangement of the second red driving circuits, the second green driving circuits and the second blue driving circuits in the second driving unit 200b, that is, the relative position of the second red driving circuits, the second green driving circuits and the second blue driving circuits in the first driving unit 200a is the same as the relative position of the second red driving circuits, the second green driving circuits and the second blue driving circuits in the second driving unit 200b.

For example, if the second red driving circuits, the second green driving circuits and the second blue driving circuits in the first driving unit 200a are arranged sequentially in the first direction X, the second red driving circuits, the second green driving circuits and the second blue driving circuits in the second driving unit 200b are arranged sequentially in the first direction X.

Exemplarily, as shown in FIG. 2 and FIG. 4, the arrangement of a plurality of first sub-pixels 110 is the same as the arrangement of a plurality of second sub-pixels 120 to reduce the display difference between the first display area AA1 and the second display area AA2.

Exemplarily, an area of the first sub-pixel 110 is less than an area of the second sub-pixel 120 to further increase the light transmittance of the first display area AA1.

In some embodiments, a size of the first driving unit 200a is the same as a size of the second driving unit 200b to further improve the display uniformity of the second display area AA2.

Exemplarily, as shown in FIG. 3 and FIG. 5, a size of the first pixel driving circuit 210 is the same as a size of the virtual area 230, and a size of the N second pixel driving circuits 220 in the first driving unit 200a is the same as a size of the N second pixel driving circuits 220 in the second driving unit 200b, so as to further improve the display uniformity of the second display area AA2.

In some embodiments, a virtual circuit is arranged in the virtual area 230. The virtual circuit may be arranged in a variety of ways. The virtual circuit may include one or more metal layers, and/or the virtual circuit may include at least one of a thin film transistor, a capacitor electrode plate, and a metal wiring. By arranging the virtual circuit in the virtual area 230, the display nonuniformity between the virtual area 230 and the area where the first pixel driving circuit 210 is located can be reduced, thereby further improving the display uniformity of the second display area AA2.

Exemplarily, a structure of the virtual circuit is the same as a structure of the first pixel driving circuit 210, so that the display effect of the virtual area 230 is the same as the display effect of the area where the first pixel driving circuit 210 is located, which can further improve the display uniformity of the second display area AA2.

In some embodiments, the first driving units 200a and the second driving units 200b are uniformly distributed in the second display area AA2, that is, a distance between two adjacent first driving units 200a, a distance between two adjacent second driving units 200b, and a distance between a first driving unit 200a and a second driving unit 200b that are adjacent are all equal, which can further improve the display uniformity of the second display area AA2.

Exemplarily, if N is an even number and the N second pixel driving circuits 220 in the first driving unit 200a are arranged side by side in the first direction, the first pixel driving circuit 210 is located in the middle of the N second pixel driving circuits 220 in the first direction. Alternatively, if N is an even number and the N second pixel driving circuits 220 in the first driving unit 200a are arranged side by side in the second direction, the first pixel driving circuit 210 is located in the middle of the N second pixel driving circuits 220 in the second direction.

As shown in FIG. 3, if N is four and the four second pixel driving circuits 220 are arranged side by side in the first direction, the first pixel driving circuit 210 is located in the middle of the N second pixel driving circuits 220 in the first direction.

In some embodiments, in the first driving unit 200a, the first pixel driving circuits 210 are located among the N second pixel driving circuits 220. For example, as shown in FIG. 5, if N is three and the three second pixel driving circuits 220 are arranged in the first direction, the first pixel driving circuit 210 is located among the three second pixel driving circuits 220, one second pixel driving circuit 220 is arranged at one side of the first pixel driving circuit 210, and two second pixel driving circuits 220 are arranged at the other side of the first pixel driving circuit 210.

In some embodiments, the first pixel driving circuits 210 and the virtual areas 230 are uniformly distributed in the second display area AA2. For example, if the number of the first pixel driving circuits 210 is m and the number of the virtual areas 230 is n, the m first pixel driving circuits 210 and the n virtual areas are uniformly distributed in the second display area AA2, that is, a distance between any two adjacent first pixel driving circuits 210, a distance between any two adjacent virtual areas 230, and a distance between a first pixel driving circuit 210 and a virtual area 230 that are adjacent are all equal.

In these embodiments, the first pixel driving circuits 210 and the virtual areas 230 are uniformly distributed in the second display area AA2, which can guarantee the display uniformity of the second display area AA2.

In some embodiments, as shown in FIG. 3 and FIG. 5, a structure of the first driving unit 200a is the same as a structure of the second driving unit 200b, which further simplifies the layout and fabrication of the pixel driving circuits.

In some embodiments, as shown in FIG. 3 and FIG. 5, a size of the first driving unit 200a is the same as a size of the second driving unit 200b, which further guarantees the display uniformity of the second display area AA2.

In some embodiments, a relative position of the first pixel driving circuits 210 and the N second pixel drive circuits 220 in the first driving unit 200a is the same as a relative position of the virtual circuits 230 and the N second pixel driving circuits 220 in the second driving unit 200b, which further simplifies the layout and fabrication of the pixel driving circuits.

For example, if N is three and the three second pixel driving circuits 220 are arranged sequentially along the first direction X, the first pixel driving circuit 210 in the first driving unit 200a is located at one side of the three second pixel driving circuits 220 in the first direction X, the virtual area 230 in the second driving unit 200b is also located at one side of the three second pixel driving circuits 220 in the first direction X, and the first pixel driving circuit 210 and the virtual area 230 are located at a same side of the three second pixel driving circuits 220.

In some embodiments, as shown in FIG. 2 to FIG. 5, the N second sub-pixels 120 driven by the N second pixel driving circuits 220 form a sub-pixel unit 100a, and a size of the first driving unit 200a and/or the second driving unit 200b fits a size of the sub-pixel unit 100a. FIG. 2 and FIG. 3 show an embodiment in which the size of the first driving unit 200a and/or the second driving unit 200b fits the size of the sub-pixel unit 100a, and FIG. 4 and FIG. 5 show another embodiment in which the size of the first driving unit 200a and/or the second driving unit 200b fits the size of the sub-pixel unit 100a.

In these embodiments, when the first pixel driving circuit 210 or the virtual area 230 is inserted into the N second pixel driving circuits 220, the size of the first driving unit 200a and/or the second driving unit 200b may fit the size of the sub-pixel unit 100a by changing the wiring, the wiring size, etc., so that the position of the second pixel driving circuits 220 further fits the position of the second sub-pixels 120 driven by the second pixel driving circuits 220, the connection between the second pixel driving circuits 220 and the second sub-pixels 120 will not be affected by the arrangement of the first pixel driving circuit 210 or the virtual area 230 in the second display area AA2, and the normal display of the second display area AA2 is guaranteed.

In some embodiments, an orthographic projection of the first driving unit 200a in a thickness direction at least partially overlaps an orthographic projection of the sub-pixel unit 100a driven by the first driving unit 200a in the thickness direction, so as to reduce a distance between the first driving unit 200a and the sub-pixel unit 100a driven by the first driving unit 200a, reduce the length of the wiring, and improve the stability of signal transmission. The thickness direction is perpendicular to a plane defined by the first direction X and the second direction Y.

In some embodiments, an orthographic projection of the second driving unit 200b in the thickness direction at least partially overlaps an orthographic projection of the sub-pixel unit 100a driven by the second driving unit 200b in the thickness direction, so as to reduce a distance between the second driving unit 200b and the sub-pixel unit 100a driven by the second driving unit 200b, reduce the length of the wiring, and improve the stability of signal transmission.

In some embodiments, as shown in FIG. 2 to FIG. 5, a plurality of sub-pixel units 100a are arranged along the first direction X and the second direction Y, and a size of the sub-pixel unit 100a in the first direction X is equal to a size of the first driving unit 200a in the first direction X. If the first driving units 200a are arranged according to the arrangement of the sub-pixels, the misalignment between the first driving units 200a and the sub-pixel units 100a in the first direction X can be reduced, and the distance between the first driving unit 200a and the sub-pixel unit 100a driven by the first driving unit 200a can be reduced.

In some embodiments, the size of the sub-pixel unit 100a in the first direction X is equal to a size of the second driving unit 200b in the first direction X. If the second driving units 200b are arranged according to the arrangement of the sub-pixels, the misalignment between the second driving units 200b and the sub-pixel units 100a in the first direction X can be reduced, and the distance between the second driving unit 200b and the sub-pixel unit 100a driven by the second driving unit 200b can be reduced.

In some embodiments, a size of the sub-pixel unit 100a in the second direction Y is equal to a size of the first driving unit 200a in the second direction Y. If the first driving units 200a are arranged according to the arrangement of the sub-pixels, the misalignment between the first driving units 200a and the sub-pixel units 100a in the second direction Y can be reduced, and the distance between the first driving unit 200a and the sub-pixel unit 100a driven by the first driving unit 200a can be reduced.

In some embodiments, the size of the sub-pixel unit 100a in the second direction Y is equal to a size of the second driving unit 200b in the second direction Y. If the second driving units 200b are arranged according to the arrangement of the sub-pixels, the misalignment between the second driving units 200b and the sub-pixel units 100a in the second direction Y can be reduced, and the distance between the second driving unit 200b and the sub-pixel unit 100a driven by the second driving unit 200b can be reduced.

In some embodiments, as shown in FIG. 3, if the sub-pixels are arranged in an array along the first direction X and the second direction Y, the first direction X is a row direction and the second direction Y is a column direction, and two adjacent rows of sub-pixels overlap each other or two adjacent columns of sub-pixels overlap each other, the size of the sub-pixel unit 100a in the first direction X is an average size of the sub-pixel units 100a in the first direction X, and the size of the sub-pixel unit 100a in the second direction Y is an average size of the sub-pixel units 100a in the second direction Y. For example, if the display panel includes P columns of sub-pixel units 100a and a size of the display panel in the first direction X is Q, the size of the sub-pixel unit 100a in the first direction X may be Q/P. If the display panel includes K rows of sub-pixel units 100a and a size of the display panel in the second direction Y is S, the size of the sub-pixel unit 100a in the second direction Y is S/K.

In some embodiments, the plurality of sub-pixels form a pixel arrangement structure including a plurality of repeating units arranged repeatedly, the sub-pixel unit 100a includes M repeating units, and M is a positive integer.

In these embodiments, the repeating units are repeatedly arranged to form the pixel arrangement structure, and if the sub-pixel unit 100a includes M repeating units, the N second pixel driving circuits 220 drive the M repeating units, therefore the N second pixel driving circuits 220 can be arranged repeatedly to drive the second sub-pixels 120 located in the second display area AA2, and thus the first driving unit 200a or the second driving unit 200b including the N second pixel driving circuits 220 can be arranged repeatedly to drive the second sub-pixels 120 located in the second display area AA2, which can simplify the fabrication and wiring of the driving circuits.

In some embodiments, M may be a positive integer such as 1, 2, 3, etc. For example, if M is 1 and the repeating unit includes three sub-pixels, N is 3, the first driving unit 200a includes three second pixel driving circuits 220 and one first pixel driving circuit 210 and is configured to drive three second sub-pixels 120 to display, and the second driving unit 200b includes three second pixel driving circuits 220 and one virtual area 230 and is configured to drive three second sub-pixels 120 to display.

In some other embodiments, for example, M is 2 and the repeating unit includes four sub-pixels, e.g., the repeating unit includes one red sub-pixel, one blue sub-pixel and two green sub-pixels, then N is 8. The first driving unit 200a includes eight second pixel driving circuits 220 and one first pixel driving circuit 210 and is configured to drive the eight second sub-pixels 120 of the two repeating units to display. The second driving unit 200b includes eight second pixel driving circuits 220 and one virtual area 230 and is configured to drive the eight second sub-pixels 120 of the two repeating units to display.

In some embodiments, the plurality of sub-pixels form a plurality of display units for emitting white light, the sub-pixel unit 100a includes M display units, and M is a positive integer.

In these embodiments, if the sub-pixel unit 100a includes M display units, the first driving unit 200a and the second driving unit 200b are respectively configured to drive the M display units to display and are arranged according to the display units, which can improve the effect of the first driving unit 200a and the second driving unit 200b on the display.

In some embodiments, the plurality of sub-pixels are distributed in an array along the first direction X and the second direction Y, and the first pixel driving circuit 210 and the first sub-pixels 110 driven by the first pixel driving circuit 210 are arranged in a same row along the first direction X.

In these embodiments, the first pixel driving circuit 210 is connected with the first sub-pixels 110 and drives the first sub-pixels 110 to display through signal lines, and if the first pixel driving circuit 210 and the first sub-pixels 110 driven by the first pixel driving circuit 210 are arranged in a same row, at least part of the signal lines can extend in the first direction X, so that the bending of the signal lines is reduced and the transmission stability of the signal lines is improved.

In some embodiments, the signal lines include a first signal line and a second signal line, the first signal line is a scan signal line and extends in the first direction X, therefore the scan signal line needs not to be bent, so as to simplify the arrangement of the scan signal line. In some embodiments, the first signal line is configured to connect the first pixel driving circuits 210 for driving a plurality of first sub-pixels 110 arranged in the first direction X.

In some embodiments, the second signal line is a data signal line and is bent to connect the first pixel driving circuits 210 for driving a plurality of first sub-pixels 110 arranged in the second direction Y.

In some embodiments, along the first direction X, the first pixel driving circuits 210 are located at a side of the virtual areas 230 close to the first display area AA1.

In these optional embodiments, the first pixel driving circuits 210 are relatively close to the first sub-pixels 110, which can reduce the extension distance of the signal lines and facilitate the arrangement of the signal lines.

In some embodiments, the second display area AA2 includes a main display area and a transition area, the transition area is located at a side of the main display area facing the first display area AA1, that is, the transition area is located between the main display area and the first display area AA1, and a distance between the transition area and the first display area AA1 is less than a distance between the main display area and the first display area AA1. The first pixel driving circuits 210 are located in the transition area, and the virtual areas 230 are located in the main display area, so that the distance between the first pixel driving circuits 210 and the first display area AA1 is relatively small, and the wiring length between the first pixel driving circuits 210 and the first sub-pixels 110 can be reduced.

In some embodiments, an average distance between the plurality of first pixel driving circuits 210 and the first display area AA1 is less than an average distance between the plurality of virtual areas 230 and the first display area AA1. A distance between a single first pixel driving circuit 210 and the first display area AA1 refers to a minimum distance between a center of the single first pixel driving circuit 210 and a center of the first display area AA1, and the average distance between the plurality of first pixel driving circuits 210 and the first display area AA1 is an average of the distances between the plurality of first pixel driving circuits 210 and the first display area AA1. Similarly, the average distance between the plurality of virtual areas 230 and the first display area AA1 refers to an average of the distances between the plurality of virtual areas 230 and the first display area AA1. The first pixel driving circuit 210 is closer to the first display area AA1, so that the first pixel driving circuit 210 is closer to the first sub-pixels 110, the extension distance of the signal lines can be reduced to facilitate the arrangement of the signal lines.

In some embodiments, the first display area AA1 is arranged symmetrically with respect to a first symmetry axis M that extends in the second direction Y and passes through the center of the first display area AA1, the plurality of first pixel driving circuits 210 are distributed symmetrically with respect to the first symmetry axis M, and the first pixel driving circuit 210 and the first sub-pixels 110 driven by the first pixel driving circuit 210 are located at a same side of the first symmetry axis M, so as to further reduce the distance between the first pixel driving circuit 210 and the first sub-pixels 110 driven by the first pixel driving circuit 210, which reduces the wiring distance.

In some embodiments, the circuit structure of the first pixel driving circuit 210 is any of a 2T1C circuit, a 7T1C circuit, a 7T2C circuit, or a 9T1C circuit. Herein, the “2T1C circuit” refers to the pixel driving circuit including two thin film transistors (T) and one capacitor (C), and the same applies to the “7T1C circuit”, “7T2C circuit”, “9T1C circuit” and the like.

In some embodiments, the circuit structure of the second pixel driving circuit 220 is any of the 2T1C circuit, the 7T1C circuit, the 7T2C circuit, or the 9T1C circuit.

In some embodiments, a size of the first sub-pixel 110 is less than a size of the second sub-pixel 120 of a same color, which can reduce the space occupied by the first sub-pixels 110 in the first display area AA1, so that an area of the non-light-emitting area in the first display area AA1 is greater, which is beneficial for increasing the light transmittance of the first display area AA1.

In some embodiments, the first sub-pixels 110 and the first pixel driving circuits 210 are arranged in a one-to-one correspondence. Each first sub-pixel 110 is driven by a corresponding first pixel driving circuit 210, which improves the display effect of the display panel 100.

In some embodiments, two or more adjacent first sub-pixels 110 of a same color are connected with a same first pixel driving circuit 210 to facilitate the wiring of the display panel 100.

Referring to FIG. 6, FIG. 6 shows a cross-sectional view at B-B in FIG. 2.

In some embodiments, as shown in FIG. 6, the display panel 100 further includes: a substrate 101; and a pixel definition layer 102 located at one side of the substrate 101 and including first pixel openings K1 located in the first display area AA1; the first sub-pixel 110 includes a first light-emitting structure 111, a first electrode 112, and a second electrode 113, the first light-emitting structure 111 is located in the first pixel opening K1, the first electrode 112 is located at a side of the first light-emitting structure 111 facing the substrate 101, and the second electrode 113 is located at a side of the first light-emitting structure 111 away from the substrate 101. One of the first electrode 112 and the second electrode 113 is an anode, and the other is a cathode.

The substrate 101 may be made of light-transmitting materials such as glass or polyimide (PI).

In some embodiments, the pixel definition layer 102 further includes second pixel openings K2 located in the second display area AA2. In some embodiments, the second sub-pixel 120 includes a second light-emitting structure 121, a third electrode 122, and a fourth electrode 123. The second light-emitting structure 121 is located in the second pixel opening K2, the third electrode 122 is located at a side of the second light-emitting structure 121 facing the substrate 101, and the fourth electrode 123 is located at a side of the second light-emitting structure 121 away from the substrate 101. One of the third electrode 122 and the fourth electrode 123 is an anode, and the other is a cathode.

In the embodiment, for example, the first electrode 112 and the third electrode 122 are anodes, and the second electrode 113 and the fourth electrode 123 are cathodes.

The first light-emitting structure 111 and the second light-emitting structure 121 may respectively include an OLED light-emitting layer, and according to design requirements, the first light-emitting structure 111 and the second light-emitting structure 121 may further respectively include at least one of a hole inject layer, a hole transport layer, an electron inject layer, or an electron transport layer.

In some embodiments, the first electrode 112 is a light-transmitting electrode. In some embodiments, the first electrode 112 includes an indium tin oxide (ITO) layer or an indium zinc oxide layer. In some embodiments, the first electrode 112 is a reflective electrode including a first light-transmitting conductive layer, a reflective layer on the first light-transmitting conductive layer, and a second light-transmitting conductive layer on the reflective layer. The first light-transmitting conductive layer and the second light-transmitting conductive layer may be ITO, indium zinc oxide, and the like, and the reflective layer may be a metal layer made of, for example, silver. The third electrode 122 may be made of the same material as the first electrode 112.

In some embodiments, the second electrode 113 includes a magnesium-silver alloy layer. The fourth electrode 123 may be made of the same material as the second electrode 113. In some embodiments, the second electrode 113 and the fourth electrode 123 may be interconnected as a common electrode.

In some embodiments, an orthographic projection of each first light-emitting structure 111 on the substrate 101 consists of one first graphic unit or two or more first graphic units jointed together, and the first graphic unit includes at least one selected from a group including a round shape, an oval shape, a dumb-bell shape, a gourd shape and a rectangle shape.

In some embodiments, an orthographic projection of each first electrode 112 on the substrate 101 consists of one second graphic unit or two or more second graphic units jointed together, and the second graphic unit includes at least one selected from a group including a round shape, an oval shape, a dumb-bell shape, a gourd shape and a rectangle shape.

In some embodiments, an orthographic projection of each second light-emitting structure 121 on the substrate 101 consists of one third graphic unit or two or more third graphic units jointed together, and the third graphic unit includes at least one selected from a group including a round shape, an oval shape, a dumb-bell shape, a gourd shape and a rectangle shape.

In some embodiments, an orthographic projection of each third electrode 122 on the substrate 101 consists of one fourth graphic unit or two or more fourth graphic units jointed together, and the fourth graphic unit includes at least one selected from a group including a round shape, an oval shape, a dumb-bell shape, a gourd shape and a rectangle shape.

Exemplarily, the display panel 100 may further include an encapsulation layer, and a polarizer and a cover plate located on the encapsulation layer. Alternatively, the cover plate may be directly arranged on the encapsulation layer without the polarizer, or at least the cover plate may be directly arranged on the encapsulation layer in the first display area AA1 without the polarizer, so as to prevent the polarizer from affecting the light collection amount of the photosensitive component correspondingly disposed under the first display area AA1. In some embodiments, the polarizer may also be arranged on the encapsulation layer in the first display area AA1.

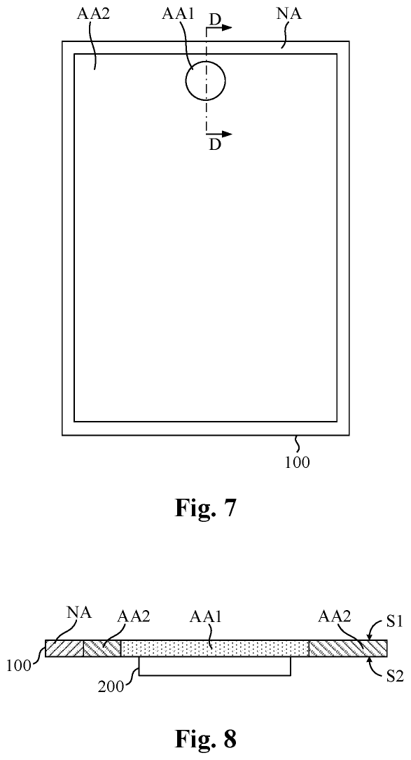

Referring to FIG. 7 and FIG. 8, FIG. 7 shows a schematic structural diagram of a display apparatus according to the embodiments of the present application, and FIG. 8 shows a cross-sectional view at D-D in FIG. 7.

As shown in FIG. 7 and FIG. 8, the display apparatus according to the second aspect of the present application may include the display panel 100 according to any of the implementations described above. In the display apparatus according to the embodiments, the display panel 100 may be the display panel 100 in one of the above-mentioned embodiments and includes the first display area AA1 and the second display area AA2, and the light transmittance of the first display area AA1 is greater than the light transmittance of the second display area AA2.

The display panel 100 includes a first surface S1 and a second surface S2 opposite to each other, and the first surface S1 is the display surface. The display apparatus further includes a photosensitive component 200 located at a side of the display panel 100 corresponding to the second surface S2, and the photosensitive component 200 corresponds to the position of the first display area AA1.

The photosensitive component 200 may be an image capturing component for capturing external image information. In the embodiments, the photosensitive component 200 is a complementary metal oxide semiconductor (CMOS) image capturing component. In some other embodiments, the photosensitive component 200 may be other image capturing component such as a charge-coupled device (CCD) image capturing component. The photosensitive component 200 may not be limited to an image capturing component, for example, in some embodiments, the photosensitive component 200 may be a light sensor such as an infrared sensor, a proximity sensor, an infrared lens, a flood sensing element, an ambient light sensor, and a dot matrix projector. In addition, other components may be integrated at the side of the display panel 100 of the display apparatus corresponding to the second surface S2, such as a telephone receiver or a speaker.

In the display apparatus according to the embodiments of the present application, the light transmittance of the first display area AA1 is greater than the light transmittance of the second display area AA2, so that the photosensitive component 200 can be integrated at the back of the first display area AA1 of the display panel 100 to realize under-screen integration for the photosensitive component 200 such as the image capturing component, while the first display area AA1 can display images, the display area of the display panel 100 is increased, and a full-screen design is achieved for the display apparatus.

The above embodiments of the present application do not exhaustively describe all the details, nor do they limit the present application to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims and the full scope and equivalents of the claims.

What is claimed is:

1. A display panel, comprising a first display area and a second display area, a light transmittance of the first display area being greater than a light transmittance of the second display area, the display panel comprising:
a plurality of sub-pixels comprising first sub-pixels located in the first display area and second sub-pixels located in the second display area;
pixel driving circuits located in the second display area and comprising first driving units and second driving units, each of the first driving units comprising one or more first pixel driving circuits configured to drive the first sub-pixels and N second pixel driving circuits configured to drive the second sub-pixels, each of the second driving units comprising one or more virtual areas and N second pixel driving circuits configured to drive the second sub-pixels, an arrangement of the N second pixel driving circuits in the first driving unit being the same as an arrangement of the N second pixel driving circuits in the second driving unit, and N being a positive integer greater than or equal to 2.

2. The display panel according to claim 1, wherein a size of the first driving unit is the same as a size of the second driving unit.

3. The display panel according to claim 1, wherein a size of the first pixel driving circuit is the same as a size of the virtual area.

4. The display panel according to claim 1, wherein a relative position of the first pixel driving circuits and the N second pixel driving circuits in the first driving unit is the same as a relative position of the virtual areas and the N second pixel driving circuits in the second driving unit.

5. The display panel according to claim 1, wherein in the first driving unit, the first pixel driving circuits are located among the N second pixel driving circuits.

6. The display panel according to claim 1, wherein a virtual circuit is arranged in the virtual area.

7. The display panel according to claim 6, wherein a structure of the virtual circuit is the same as a structure of the first pixel driving circuit.

8. The display panel according to claim 1, wherein the first driving units and the second driving units are uniformly distributed in the second display area.

9. The display panel according to claim 1, wherein the first pixel driving circuits and the virtual areas are uniformly distributed in the second display area.

10. The display panel according to claim 1, wherein N second sub-pixels driven by the N second pixel driving circuits form a sub-pixel unit, and a size of at least one of the first driving unit and the second driving unit fits a size of the sub-pixel unit.

11. The display panel according to claim 10, wherein an orthographic projection of the first driving unit in a thickness direction of the display panel at least partially overlaps an orthographic projection of the sub-pixel unit driven by the first driving unit in the thickness direction; or
an orthographic projection of the second driving unit in the thickness direction of the display panel at least partially overlaps an orthographic projection of the sub-pixel unit driven by the second driving unit in the thickness direction.

12. The display panel according to claim 10, wherein the display panel comprises a plurality of sub-pixel units, the plurality of sub-pixel units are arranged in a first direction and a second direction,
a size of the sub-pixel unit in the first direction is equal to a size of at least one of the first driving unit and the second driving unit in the first direction; or
a size of the sub-pixel unit in the second direction is equal to a size of at least one of the first driving unit and the second driving unit in the second direction.

13. The display panel according to claim 10, wherein the plurality of sub-pixels form a pixel arrangement structure comprising a plurality of repeating units arranged repeatedly, the sub-pixel unit comprises M repeating units, and M is a positive integer.

14. The display panel according to claim 10, wherein the plurality of sub-pixels form a plurality of display units configured to emit white light, the sub-pixel unit comprises M display units, and M is a positive integer.

15. The display panel according to claim 1, wherein the plurality of sub-pixels are distributed in an array along a first direction and a second direction, and the first pixel driving circuit and the first sub-pixels driven by the first pixel driving circuit are arranged in a same row along the first direction.

16. The display panel according to claim 1, wherein the second display area comprises a main display area and a transition area, the transition area is located at a side of the main display area close to the first display area, the first pixel driving circuits are located in the transition area, and the virtual areas are located in the main display area.

17. The display panel according to claim 16, wherein a number of the first pixel driving circuits is two or more, a number of the virtual areas is two or more, and an average distance between the two or more first pixel driving circuits and the first display area is smaller than an average distance between the two or more virtual areas and the first display area.

18. The display panel according to claim 1, further comprising:
a substrate; and
a pixel definition layer located on the substrate and comprising first pixel openings located in the first display area,
wherein the first sub-pixel comprises a first light-emitting structure, a first electrode and a second electrode, the first light-emitting structure is located in the first pixel opening, the first electrode is located at a side of the first light-emitting structure facing the substrate, and the second electrode is located at a side of the first light-emitting structure away from the substrate.

19. The display panel according to claim 18, wherein an orthographic projection of each first light-emitting structure on the substrate consists of one first graphic unit or two or more first graphic units jointed together, and the first graphic unit comprises at least one selected from a group comprising a round shape, an oval shape, a dumb-bell shape, a gourd shape and a rectangle shape; and
an orthographic projection of each first electrode on the substrate consists of one second graphic unit or two or more second graphic units jointed together, and the second graphic unit comprises at least one selected from a group comprising a round shape, an oval shape, a dumb-bell shape, a gourd shape and a rectangle shape.

20. A display apparatus, comprising the display panel according to claim 1.
